(19) United States
(12) Patent Application Publication
(10) Pub. No.: US 2009/0073665 A1
(43) Pub. Date: Mar. 19, 2009

(54) Memory card

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/976,096

(22) Filed: Oct. 22, 2007

(30) Foreign Application Priority Data
Sep. 7, 2007 (TW) 96133411

(51) Int. Cl. H01L 25/065; G06F 1/16

(52) U.S. Cl. 361/737; 257/E25.01

(57) ABSTRACT

A memory card includes a first cover, a second cover, a set of leads and a memory component. The first cover has a set of openings; the second cover is combined with the first cover to define a holding space. The leads are arranged in the holding space, and their one end are emerged from the openings as an exterior terminal. The memory component arranged in the holding space includes a chip substrate and at least one function component electrically connected with the chip substrate, wherein the chip substrate has a set of conductive pads electrically connected to the other end of the leads. According to the above-mentioned structure, the memory card with smaller chip substrate is designed to reduce manufacture cost.

### BACKGROUND OF THE INVENTION

1. Field of the Invention

The present invention relates to a memory card, particularly to a memory card with a relatively smaller chip substrate.

2. Description of the Prior Art

Portable electronic devices are not only slim and short, but possessed of more powerful functions. In contrast, built-in memory of portable electronic devices is obviously inadequate. Therefore, the existing portable electronic devices have capabilities to support the memory card to compensate for the lack of built-in memory.

Please refer to FIG. 1a, the structure of a prior memory card 1 includes a first cover 11, a second cover 12, and a memory component 13. The first cover 11 which has an opening 111 is combined with the second cover 12 to form a shell with memory card shape. Memory component 13 arranged between the first cover 11 and the second cover 12 is used for implementing the functions of the memory card 1. For example, the memory component 13 includes a chip substrate 131, and function components, such as a memory chip 132 and a control unit 133 etc., are arranged on and electrically connected with the chip substrate 131. The chip substrate 131 further has a conductive pad 134 which is emerged from the opening 111 as an exterior terminal. Electronic devices can be electrically connected with the memory component 13 through the exterior terminal to perform the functions of the memory component 13, such as accessing memory chip 132.

Please refer to FIG. 1b and take a secure digital card (SD card) as an example, in order to let exterior terminal 14 formed by the conductive pad 134 follow the standard specification of the SD card, the chip substrate 131 requires the corresponding size. Therefore, owing to the structure of the memory card 1, the size of the chip substrate 131 can not be effectively decreased.

Cost reduction has been the goal pursued by the industry. For this reason, improving the structure of memory cards with relatively lower manufacturing costs is now an urgent target.

### SUMMARY OF THE INVENTION

One objective of the present invention is to provide a memory card with relatively smaller chip substrate to reduce production costs of the memory card.

To achieve the above-mentioned objective, the present invention proposes a memory card in one embodiment, which includes: a first cover, a second cover, a set of leads, and a memory component. The first cover has a set of openings; the second cover is combined with the first cover to define a holding space. The leads are arranged in the holding space, and their one end are emerged from the openings as an exterior terminal. The memory component arranged in the holding space includes a chip substrate and at least one function component electrically connected with the chip substrate, wherein the chip substrate has a set of conductive pads electrically connected to the other end of the leads.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1a is a cross-sectional diagram schematically showing a disassembly structure of a memory card according to a prior art;

FIG. 1b is a bottom-view diagram schematically showing a secure digital card according to a prior art;

FIG. 2a is a cross-sectional diagram schematically showing a disassembly structure of a memory card according to a preferred embodiment of the present invention; and

FIG. 2b is a top-view diagram schematically showing a memory card without the second cover according to a preferred embodiment of the present invention.

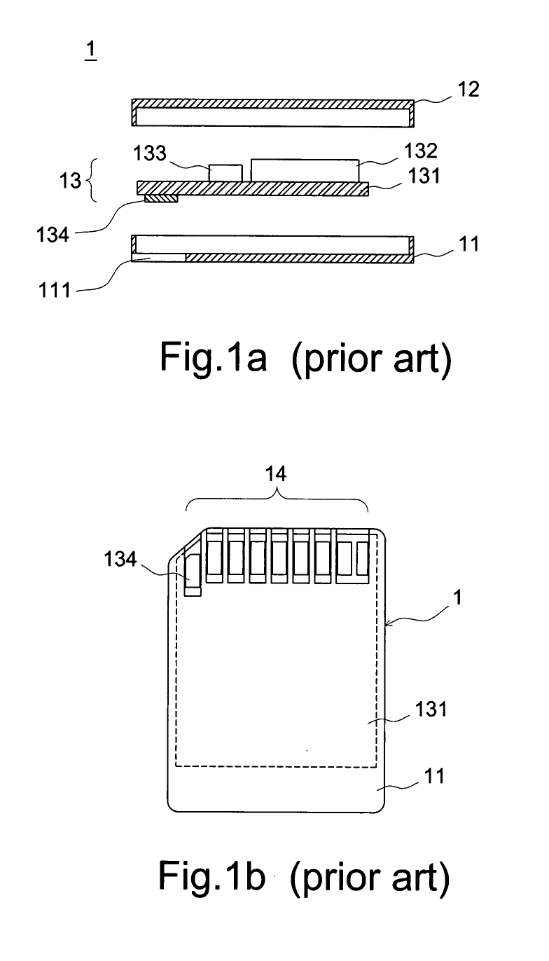

### DETAILED DESCRIPTION OF THE INVENTION

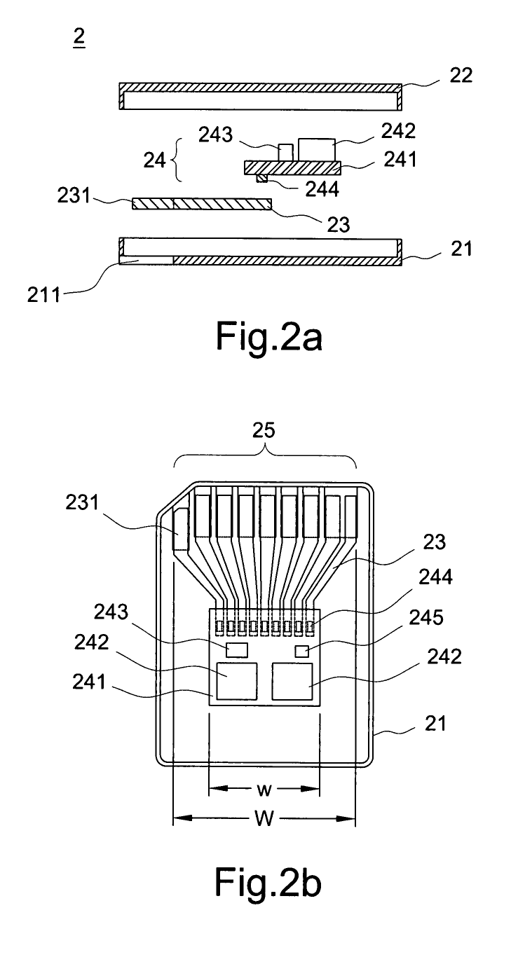

Please refer to FIG. 2a and FIG. 2b to illustrate a memory card 2 according to a preferred embodiment of the present invention. The memory card 2 includes a first cover 21, a second cover 22, a set of leads 23, and a memory component 24. The first cover 21 has a set of openings 211. The second cover 22 is combined with the first cover 21 in the appropriate manner to define a holding space and form a shell with memory card shape. As shown in FIG. 2b, examples of the memory card include but are not limited to secure digital card (SD card) and multi media card (MMC). The first cover 21 and the second cover 22 can be combined by bonding with an adhesive or fusing by high frequency.

The leads 23 are arranged in the holding space formed by the first cover 21 and the second cover 22, and their one end are emerged from the corresponding openings 211 as an exterior terminal 25. It should be noted that, a metal layer can be formed on the surface of exterior terminal 25 to increase the conductivity of exterior terminal 25, for example, the metal layer can be a gold (Au) layer.

Continuation of the note, memory component 24 arranged in the holding space is used for implementing functions of the memory card. For example, memory component 24 comprises a chip substrate 241 and at least one function component. The function component electrically connected with the chip substrate 241 comprises a memory chip 242 and a control unit 243, in preferred embodiment, further comprises at least one passive component 245 (as shown in FIG. 2b). The chip substrate 241 has a set of conductive pads 244 used for electrically connecting to the other end of the leads 23. In preferred embodiment, a metal layer can be formed on the surface of conductive pad 244, such as gold (Au) layer, to increase the conductivity of conductive pad 244. Based on the above structure, an electronic device can be electrically connected to the memory card 2 via the exterior terminal 25. Because the leads 23 are electrically connected with the memory component 24, the electronic device can be electrically connected to the memory component 24 to perform functions of the memory card 2, such as accessing memory chip 242.

It should be noted that, the structure of the memory component 24 can be implemented by various prior art. For example, all kinds of chips, such as memory chip 242, can be arranged on the chip substrate 241 by its non-active surface and electrically connected to the chip substrate 241 by wire; or chips can be flipped to be arranged on the chip substrate 241 by its active surface and electrically connected to the chip substrate 241 by conductive bump. Further, chips can be arranged on the chip substrate 241 side by side or by stacked-type. Furthermore, various components of memory component 24 can be packaged together according to system in package (SIP).

According to the structure of the memory card, the size of its chip substrates is not restricted by the standard specification of memory card that exterior terminal follows. Please refer to FIG. 2b, due to one end 231 of the leads 23 are regards as the exterior terminal 25 electrically connected to electronic device, therefore, the width W of the exterior terminal 25 must follows the standard specification of memory card. The other end of the leads 23 can be arbitrarily arranged according to the design, therefore the width w of the chip substrate 241 can be less than or equal to the width W of the exterior terminal 25.

To sum up the foregoing descriptions, the size of the chip substrate arranged in the memory card of the present invention is not restricted by the standard specification of memory card that exterior terminal follows, therefore, memory cards with relatively smaller chip substrate can be designed to reduce material costs of the memory card. In addition, the conductive pads of the chip substrate of the prior art are copper material, thus a thicker gold layer should be plated to improve repeatedly inserted wear resistance. As for memory cards of the present invention, because the material of the leads has a better wear resistance, only a thinner gold layer is plated on the surface of the leads, which further reduces material costs. Furthermore, memory cards of the present invention can be designed in the way that the size of the conductive pad is smaller than the prior art. Therefore, material costs of plating gold layer and total manufacture costs of the memory cards are both consequently reduced.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A memory card comprising:
a first cover having a set of openings;
a second cover combined with said first cover to define a holding space;
a set of leads arranged in said holding space, wherein one end of said leads emerges from said opening as an exterior terminal; and
a memory component arranged in said holding space and comprising a chip substrate and at least one function component electrically connected to said chip substrate, wherein said chip substrate has a set of conductive pads electrically connected to the other end of said leads.

2. A memory card according to claim 1, wherein the width of said chip substrate is less than or equal to the width of said exterior terminal.

3. A memory card according to claim 1, wherein said function component comprises a control unit, at least one memory chip, and at least one passive component.

4. A memory card according to claim 3, wherein said memory component is a system in package (SIP).

5. A memory card according to claim 1, further comprising a gold layer formed on the surface of said conductive pad.

6. A memory card according to claim 1, further comprising a gold layer formed on the surface of said exterior terminal.

7. A memory card according to claim 1, wherein said first cover and said second cover are combined by bonding with an adhesive or fusing by high frequency.

8. A memory card according to claim 1, being secure digital card or multi media card.

9. A memory card comprising:
a first cover having a set of openings;
a second cover combined with said first cover to define a holding space;
a set of leads arranged in said holding space, wherein one end of said leads emerges from said opening as an exterior terminal; and
a memory component arranged in said holding space and comprising a chip substrate and at least one function component electrically connected to said chip substrate, wherein said chip substrate has a set of conductive pads electrically connected to the other end of said leads and the width of said chip substrate is less than or equal to the width of said exterior terminal.

10. A memory card according to claim 9, wherein said function component comprises a control unit, at least one memory chip, and at least one passive component.

11. A memory card according to claim 10, wherein said memory component is a system in package (SIP).

12. A memory card according to claim 9, further comprising a gold layer formed on the surface of said conductive pad.

13. A memory card according to claim 9, further comprising a gold layer formed on the surface of said exterior terminal.

14. A memory card according to claim 9, wherein said first cover and said second cover are combined by bonding with an adhesive or fusing by high frequency.

15. A memory card according to claim 9, being secure digital card or multi media card.
